(19) United States
(12) Patent Application Publication
(10) Pub. No.: US 2018/0123588 A1
(43) Pub. Date: May 3, 2018

(54) METHOD FOR ADJUSTING A PROXIMITY SWITCH AND PROXIMITY SWITCH

(71) Applicant: IFM ELECTRONIC GMBH, Essen (DE)

(72) Inventor: Markus TAHEDL, Eriskirch (DE)

(73) Assignees: IFM ELECTRONIC GMBH, Essen (DE); IFM ELECTRONIC GMBH, Essen (DE)

(21) Appl. No.: 15/568,414

(22) PCT Filed: Apr. 8, 2016
(86) PCT No.: PCT/EP2016/057678

§ 371 Date: Oct. 20, 2017

(30) Foreign Application Priority Data
Apr. 22, 2015 (DE) 10 2015 207 265.7

(51) Int. Cl. H03K 17/965; H03K 17/945

(52) U.S. Cl. CPC H03K 17/965; H03K 2217/94021; H03K 17/945

(57) ABSTRACT

A switch and method for adjusting the switching threshold of a contactlessly operating proximity switch comprising a sensor for converting a physical variable into an electric sensor signal S(x), a control unit for evaluating the electric sensor signal S(x) and for generating a binary switching signal by comparing with a switching threshold Sein, and comprising an operating element for adjusting the switching threshold Sein according to a control value P, wherein the control value P is mapped in a non-linear manner on the movement path of the operating element, wherein the resolution of the operating element is largest when the electric sensor signal S(x) is in the vicinity of the switching threshold Sein(P) and decreases in a non-linear manner at increasing distance such that the influence of the switching threshold Sein(P) is fine in the vicinity of the current sensor signal S(x) and increasingly coarser at increasing distance.

### CROSS-REFERENCE TO RELATED APPLICATIONS

This application is a National Stage of International Application No. PCT/EP2016/057678, filed on Apr. 8, 2016, and published in German as WO2016/169781 Al on Oct. 27, 2016. This application claims the priority to German Patent Application No. 10 2015 207 265.7, filed on Apr. 22, 2015. The entire disclosures of the above applications are incorporated herein by reference.

### FIELD

The disclosure relates to a method for adjusting a proximity switch including a strip display according to the preamble of claim 1, as well as a proximity switch for carrying out the method.

### BACKGROUND

This section provides background information related to the present disclosure which is not necessarily prior art.

Contactless operating proximity switches are widely used in the automation technology. They are equipped with an inductive magnetic, capacitive, optical or ultrasound sensor, transmit a signal into a monitoring area and detect the presence or the condition of an object based on a change of a physical variable. The sensor converts the physical variable x into an electrical sensor signal S(x), usually a voltage or a current.

They are suitable for detecting an object (target) in a monitoring area, or else a medium, e.g. as capacitive level sensors for detecting electrically nonconductive materials through a container wall, or as flow monitors for the process measurement technology. Such devices are likewise manufactured and distributed by the applicant.

The electrical sensor signal is compared with the switching threshold of a comparator and converted into a binary switching signal (switching state signal). Herein, the signal is usually first digitized, processed and interpreted. The state of the switching output is usually indicated by light-emitting diodes (LEDs) in a known manner.

DE 196 23 969 B4 shows a proximity switch in which the switching threshold can be adjusted with a potentiometer. The potentiometer is connected to a resistor network such that a linear variation of the potentiometer position corresponds to a linear change in the switching distance.

For the adjustment of proximity switches with a large setting range often multi-turn potentiometers are used to achieve the necessary adjustment accuracy. The disadvantage is that several revolutions are necessary for the adjustment and no information about the direction of rotation, the limits and the current setting is available.

U.S. Pat. No. 8,456,271 B1 shows a proximity switch including a multi-turn potentiometer. The potentiometer is connected to a Geneva wheel, which at every revolution advances by one step, wherein its position can be read in a viewing window.

Another known adjustment concept is based on the operation with one or more keys. The disadvantage is a complex, less intuitive and thus not user-friendly adjustment process.

EP 0 844 464 A1 shows such a proximity switch in which the switching distance can also be set by means of a learning process (teach-in). The switching threshold and the current sensor signal are each indicated by means of an LED chain (bar graph).

DE 39 27 744 A1 shows a sensor in which an analogous electrical sensor signal is supplied to a comparator network and is indicated by a light-emitting diode chain.

Disadvantageous is that the switching thresholds of the comparators are fixed, which limits the number of switching thresholds which can be displayed to the number of comparators and also of the light-emitting diodes.

### SUMMARY

This section provides a general summary of the disclosure, and is not a comprehensive disclosure of its full scope or all of its features.

It is the object of the present disclosure to achieve a finer adjustment or a higher resolution in the strip display or adjustment in the entire adjustment range without significantly increasing the complexity of operating and strip display elements.

The essential idea of the disclosure is to scale both the operating element and the strip display in both directions in a non-linear, preferably logarithmic manner, wherein in a preferred embodiment there is a linear relationship between the operating element and the strip display elements.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

The disclosure is explained in more detail with reference to the drawings.

FIG. 1 shows a block diagram of a proximity switch according to the disclosure;

FIG. 2 shows a logarithmic scaling of the operating element according to the disclosure; and

FIG. 3 shows a more detailed block diagram of the proximity switch according to the disclosure.

FIG. 1 shows a proximity switch according to the disclosure as a block diagram, wherein the sensor 1 is configured as a capacitive sensor. A generator G generates a high-frequency alternating voltage which is supplied to one or more first electrodes. These are capacitively coupled to their environment and/or to a second electrode so that a displacement current can flow.

Corresponding reference numerals indicate corresponding parts throughout the several views of the drawings.

### DETAILED DESCRIPTION

Example embodiments will now be described more fully with reference to the accompanying drawings.

The capacitive coupling of the two electrodes is influenced by a target 2 or by a medium 2 to be monitored.

The sensor signal is rectified, filtered and supplied to a microcontroller 3 for digitization and further processing. The microcontroller 3 controls the generator G, but can also take over its function by itself. In any case, the rectifier and/or the microcontroller receives the generator signal for a phase-sensitive rectification.

The microcontroller 3 is connected to an operating element 4, a (state) strip display 5, here shown as a strip display 5 operating in point mode, and a preferably binary switching output (switching state output). Point operation means that normally only one LED lights up. For interpolation, adjacent LEDs with the same or with different brightness (duty cycle) can light up. This applies in particular to the zero point for an even number of LEDs. With higher power consumption, the strip display 5 can also be operated in a bar operation.

The operating element 4 is shown symbolically as a rotary potentiometer with a scale 8. However, it can also be configured completely differently without departing from the disclosure. For example, they may be pushbuttons, an angle sensor or else an electrical interface of any desired design. The scale 8 can, as shown, be linear or else be a circular arc or can be omitted completely.

As illustrated in FIG. 3 and explained in more detail later, the mapping of the control value P to the threshold value Sein according to the disclosure is not linear, but preferably exponential. The mapping is ideally selected in such a way that again a linear relationship is obtained with the strip display (5) which is non-linearly dependent from the sensor signal S(x) and the switching threshold Sein. In particular, a specific angular change of, for example ΔP=30°, is accurately mapped to one LED step, when a potentiometer is used in the operating element 4.

The strip display 5 is shown here as a linear strip display. However, it can also be configured as a circular arc, a sector, or any arrangement of discrete display elements. According to the disclosure it has a number of LEDs, which, however, is not intended to exclude other visible strip displays. The number of LEDs can be even or odd, depending on how the zero crossing is to be displayed. The LED marked with SA, usually a yellow LED, indicates the switching state.

The middle LED indicates the smallest difference between the sensor signal S(x) and the set switching threshold Sein. Toward the outside, the signal difference required for activating the next LED is increasingly greater in both directions, in particular, it increases logarithmically. This means that the inner elements 6 indicate a lower and the outer element 7 a larger distance of the sensor signal S(x) to the switching threshold value Sein(P) set by means of the operating element 4.

Thus, the switching operation always takes place in the center of the strip display, whereby it is indicated to the operator at any time how far the current sensor signal S(x) is away from the set switching threshold Sein in both directions, i.e. it is indicated to the operator whether the coupling between the target 2 or the medium and the sensor electrode (attenuation) is still too low or already too high for a switching operation. In addition, the position of the switching threshold Sein is even visible between two states.

Thus, any movement of the target 2 of the medium to be monitored, but also of the operating element 4 is detectable. The strip display 5 is thus operated as a dynamically scaled window over the permitted value range of the switching threshold Sein.

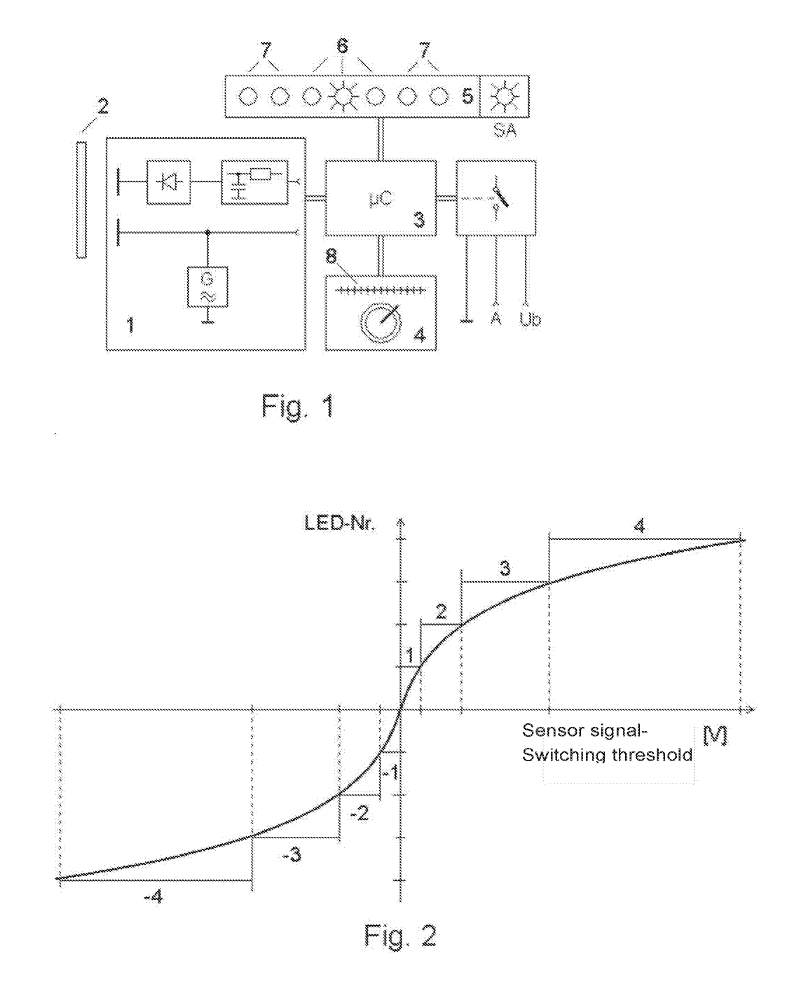

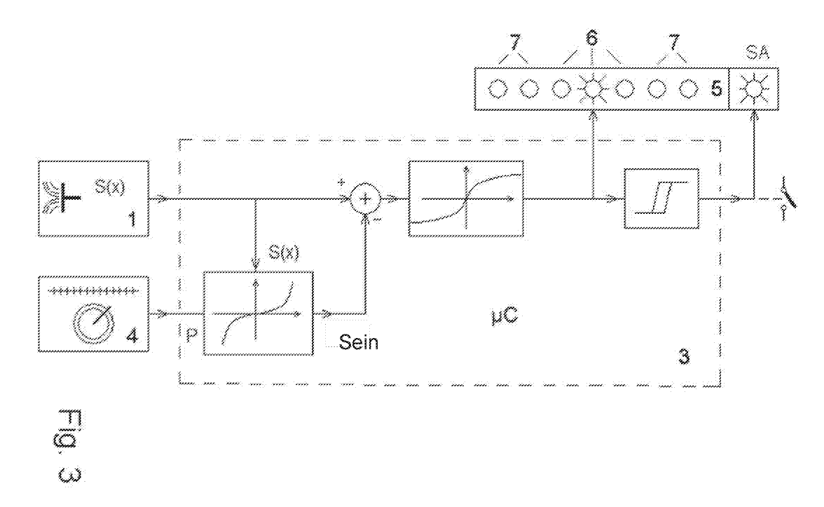

FIG. 2 shows the logarithmic scale of the strip display 5 according to the disclosure, wherein the abscissa indicates the difference between the sensor signal S(x) and the switching threshold Sein and the ordinate indicates the strip display element dependent therefrom, i.e. the number of the LED.

The scaling can be configured symmetrical or asymmetrical in both directions. It is preferably, but not necessarily logarithmic. However, according to the disclosure, the scaling is designed in such a way that the setting values are mapped non-linearly onto the movement path of the operating element 4, wherein the resolution of the operating element 4 is greatest when the electrical sensor signal S(x) is close to the switching threshold Sein(P) and decreases non-linearly with increasing distance, so that the influence of the switching threshold Sein(P) at a currently measured sensor signal S(x) is fine in its vicinity and becomes increasingly coarser with increasing distance. According to the disclosure, the operating element 4 is scaled in such a way that a nearly linear relationship between the operating element 4 and the strip display 5 is achieved.

When the strip display 5 has an odd number of elements as shown in FIG. 1, the middle element is designated with “0” and indicates whether the sensor signal S(x) is in a defined range, for example in the hysteresis range at the zero point (zero-crossing): Sein=S(x) with x=x0.

FIG. 3 shows a more detailed block diagram of the arrangement shown in FIG. 1. In particular, the signal processing in the microcontroller 3 is to be illustrated without restricting the disclosure to the software processing in a microcontroller.

For the evaluation of the sensor signal S(x) the switching threshold Sein(P) is subtracted from the sensor signal S(x) and, according to the disclosure, is mapped non-linearly, preferably logarithmic, onto the strip display 5 operating in point mode. As a result, zero is output when the sensor signal S(x) reaches the switching threshold Sein. In this case, as indicated, the middle LED lights up, i.e. the switching threshold is reached, and the binary switching output A, shown as a switch, changes its state.

The switching output deviating from the diagram can also be directly connected to the difference generation. Of course, a hysteresis is provided in order to avoid fluttering of the switching output A and the display LED SA.

The threshold value Sein is dependent on the control value P at the control element 4 and the sensor signal S(x), wherein the mapping rule is being chosen such that preferably a linear relationship between the operating element 4 and the strip display 5 is obtained. Because of the non-linear mapping of the difference signal Δ(Sein, P, . . . ) onto the strip display 5 the mapping rule is also not linear, but preferably exponential, without restricting the disclosure to an exponential relationship.

In addition, other non-linear mappings between the operating element 4 and the strip display 5, which preferably operates in point mode, are conceivable.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are to be regarded as a departure from the disclosure, and all such modifications are intended to be included within the scope of the disclosure.

1. Method for adjusting the switching threshold of a contactless operating proximity switch including a sensor for converting a physical variable into an electrical sensor signal S(x), a control unit for evaluating the electrical sensor signal S(x) and for generating a binary switching signal by comparing with a switching threshold Sₑᵢₙ and an operating element for adjusting the switching threshold depending on a control value P;
wherein
the control values P are mapped in a non-linear manner onto the moving path of the operating element, wherein the resolution of the operating element is greatest when the electrical sensor signal S(x) is in the vicinity of the switching threshold Sₑᵢₙ(P) and decreases non-linearly with increasing distance such that the influence of the switching threshold Sₑᵢₙ(P) at a currently measured sensor signal S(x) is fine in its vicinity, and becomes increasingly coarser with increasing distance.

2. Method according to claim 1, wherein the positive and the negative difference Δ(Sₑᵢₙ, P, . . . ) between the electrical sensor signal S(x) and the switching threshold Sₑᵢₙ(P) is indicated by means of a strip display, wherein a linear relationship exists between the scaling of the control element and the strip display.

3. Proximity switch comprising a sensor for converting a physical variable into an electrical switching signal S(x), wherein the physical variable can be influenced by a target, and wherein the magnitude of the electrical sensor signal S(x) depends on a variable x associated to the target, a control unit for evaluating the electrical sensor signal S (x) and for generating a binary switching signal by comparing with a switching threshold Sₑᵢₙ(P) which is dependent on the control value P of an operating element and a strip display, wherein
the strip display indicates the positive and the negative difference Δ(Sₑᵢₙ, P, . . . ) between the electrical sensor signal S(x) and the switching threshold Sₑᵢₙ(P) and comprises inner elements and outer elements, wherein the inner elements indicate a smaller distance and the outer elements indicate a greater distance between the electrical sensor signal S(x) and the switching threshold Sₑᵢₙ(P).

4. Proximity switch according to claim 3, wherein the strip display is scaled non-linearly, wherein the distance between the electrical sensor signal S(x) and the switching threshold Sₑᵢₙ(P) increases towards the outside in both directions starting from the center of the scale.

5. Proximity switch according to claim 4, wherein the scale is symmetrical toward the outside in both directions starting from the center of the scale.
